(19) United States
(12) Patent Application Publication
(10) Pub. No.: US 2023/0179069 A1
(43) Pub. Date: Jun. 8, 2023

(54) ELECTRIC MOTOR WITH SUPPRESSION DEVICE AND METHOD FOR ARRANGING A SUPPRESSION DEVICE ON AN ELECTRIC MOTOR

(71) Applicant: DR. FRITZ FAULHABER GMBH & CO. KG, SCHOENAICH (DE)

(72) Inventors: Florian JACOBS, STEINENBRONN (DE); Thomas SCHNEIDER, PLANKSTADT (DE)

(73) Assignee: DR. FRITZ FAULHABER GMBH & CO. KG, SCHOENAICH (DE)

(21) Appl. No.: 18/061,614

(22) Filed: Dec. 5, 2022

(30) Foreign Application Priority Data
Dec. 7, 2021 (EP) 21212852.4

(51) Int. Cl. H02K 11/02; H02K 5/22; H02K 11/30; H02K 11/40

(52) U.S. Cl. CPC H02K 11/02; H02K 5/225; H02K 11/30; H02K 11/40

(57) ABSTRACT

An electric motor with a housing, at least two terminal contacts and at least one suppression device against electromagnetic emissions, wherein the suppression device comprises at least one circuit carrier with at least one filter circuit, wherein the circuit carrier is arranged on an end side of the electric motor, and wherein the filter circuit is electrically connected to the two terminal contacts. The manufacturing effort is reduced in that at least one contact means electrically connected to the filter circuit is attached to the circuit carrier, and in that the contact means bears against a ground contact with at least partial deformation, so that the filter circuit is electrically connected to the ground contact via the contact means.

### CROSS-REFERENCE TO RELATED APPLICATIONS

This application claims the benefit of priority under 35 U.S.C. §119 to European Patent Application No. 21212852.4, filed Dec. 7, 2021, the contents of which are incorporated herein by reference in its entirety.

### BACKGROUND

The invention relates to an electric motor, in particular a mechanically commutated DC motor, with a housing, at least two terminal contacts and at least one suppression device against electromagnetic emissions. The suppression device has at least one circuit carrier, which is arranged on an end side of the electric motor. The circuit carrier has at least one filter circuit, which is electrically connected to the two terminal contacts of the electric motor.

Suppression devices for electric motors, in particular for DC motors, have long been known in the state of the art in a variety of designs. In mechanically commutated DC motors, the main source of electromagnetic emissions is in particular the brush system due to sparking and lifting of the brushes during vibration. Furthermore, pulse-width modulated control of electric motors also has an influence on electromagnetic emissions.

In order to reduce electromagnetic emissions from an electric motor, it is known to electrically connect a circuit carrier with an interference suppression circuit to the terminal contacts of the electric motor as well as to a ground contact. The suppression devices usually comprise capacitances and inductances, which are connected between the terminal contacts in a manner known per se. Ideally, such interference suppression circuits are arranged as close as possible to the electric motor itself.

From the prior art, it is known, for example, to weld the suppression device to the housing or to connect it electrically to a back iron of the electric motor with a rigid connection. By making at least one welded connection, but often also a plurality of welded connections, the assembly preparation and thus the overall assembly effort is increased.

Based on the aforementioned prior art, the present invention is based on the task of providing an electric motor as well as a method for arranging a suppression device on an electric motor, which simplify the manufacturing.

### SUMMARY

The aforementioned task is solved in a generic electric motor with the features of the described herein, namely in that at least one contact means electrically connected to the filter circuit is attached to the circuit carrier, and in that the contact means bears against a ground contact of the electric motor with at least partial deformation, so that the filter circuit is electrically connected to the ground contact via the contact means.

The electric motor is preferably a mechanically commutated DC motor or a brushless DC motor or another electric motor. In particular, it is provided that the electric motor has at least one rotor, at least one stator and an back iron. The terminal contacts supply the electric motor with the required operating voltage. In the case of a mechanically commutated DC motor, the Terminal contacts are connected to the commutator, in particular the brushes.

In particular, the circuit carrier is attached to a first end face of the electric motor. For example, the circuit carrier is formed as a conductor board, in particular as a printed circuit, or as a supporting element made of a non-conductive material. In particular, the circuit carrier is arranged on a brush cover of the electric motor. It is preferably provided to implement high-frequency shielding of the brush fire via a brush cover, the circuit carrier, a separate disc and/or a metallized coating on the motor cover.

The contact means is preferably attached to an bottom side of the circuit carrier oriented in the direction of the electric motor. When the circuit carrier is mounted on the electric motor, the contact means is deformed after contact with the ground contact so that it bears against the ground contact over as large an area as possible. The contact means is preferably deformed and/or compressed from an initial shape as a result of the assembly process and, in particular, bears against the ground contact. In particular, the contact means is at least partially elastically deformed and/or at least partially compressed. The contact means is sufficiently flexible to ensure deformation during assembly without preventing the assembly process. In the assembly state, the contact means rests on the ground contact.

The deformation results in a contact force with which the contact means rests against the ground contact of the electric motor and thus makes electrical contact with it. The contact force essentially results from the force that the contact means exerts against the deformation.

The circuit carrier is attached to the electric motor, for example by latching the circuit carrier in a form-fit and/or force-fit manner. It is also provided that the circuit carrier is attached to the electric motor by soldering the two terminal contacts of the electric motor to assigned contact areas on the circuit carrier. The soldered connections between the terminal contacts and the contact areas simultaneously take over the mechanical connection of the circuit carrier to the electric motor. The soldered connections then also take over the counterforces to the contact force resulting from the elastic deformation of the contact means.

The filter circuit preferably has capacitances in the form of capacitors and/or inductances in the form of inductors. Preferably, at least three capacitances and at least two inductances are provided. The capacitances are designed, for example, as multilayer ceramic capacitors (MLCC), X2Y-capacitors and/or feedthrough capacitors. Depending on the design, the capacitors have two or more terminals. The inductances are formed in different designs, for example as inductors or as a passive design in a conductor path. Depending on the embodiment, it is also provided that inductances are used in a coupled manner, e.g. as common-mode choke. It is also provided that the filter circuit comprises only a plurality of capacitances. Consequently, the inductances are optional.

The use of a deformable or deformed contact means has the advantage over the prior art that contacting is automatic during assembly. At the same time, the contact force resulting from the deformation ensures contacting of the ground contact even in the event of vibrations or similar mechanical influences. In addition, the circuit carrier with the filter circuit can be arranged very close to the electric motor due to the deformable contact means, which improves the filtering of electromagnetic interference.

According to a first advantageous embodiment of the electric motor, it is provided that at least two, in particular exactly two, at least three, in particular exactly three, or at least four, in particular exactly four, contact means are attached to the circuit carrier. All contact means are preferably of identical design and perform the same function. Each of the two, three or four contact means is electrically contacted with a respective ground contact or a common ground contact of the electric motor, by each contact means resting at least partially deformed against the ground contact. The above and following explanations for a single contact means apply equally to each contact means in the presence of several contact means.

This embodiment has the advantage that redundancy is created by the plurality of contacts, so that contacting between a respective ground contact and the filter circuit is always guaranteed.

According to a further embodiment of the electric motor, it has been found to be advantageous if it is provided that the ground contact against which the at least one contact means rests is formed by the housing and/or an back iron. In particular, the ground contact is electrically conductive connected to the back iron. The contact means lies deformed at least partially against the housing and/or at least partially against the back iron. For example, the housing is electrically conductive connected to the back iron so that the entire housing serves as the ground contact.

According to an embodiment of the invention, it has been found to be further advantageous if it is provided that the housing has a deformation, in particular a concave deformation, at least one location, and that the contact means rests in the deformation. Preferably, the deformation is formed in an edge region of the housing oriented in the direction of the suppression device. The arrangement of the contact means in the inwardly directed deformation of the housing, i.e. in a substantially concave indentation of the housing, ensures that the contact means does not protrude beyond the original housing geometry. It is particularly preferred that the deformation is formed by caulking. For example, the housing is caulked to a brush cover and/or to the iron back. For example, it is provided that the housing has a deformation in at least two, at least three or at least four locations, and that at least one contact means is arranged in each deformation. Each of the deformations is advantageously a caulking of the housing.

Particularly advantageously, according to a further embodiment, it is provided that the contact means is designed and arranged in such a way that it does not protrude beyond the outer contour of the housing. The contact means is preferably designed and arranged in such a way that, despite its own deformation and/or compression, it fits, in particular into the deformation of the housing, in such a way that the contact means does not protrude beyond the outer contour of the housing, in particular does not protrude in the radial direction. This is ensured, for example, by a specific selection of the material of the contact means, taking into account the initial shape of the contact means before assembly and the deformability of the material itself, e.g. via compressibility, etc.

A further embodiment of the electric motor provides that the contact means is/are at least partially elastically deformed and/or at least partially compressed. The contact means is elastically deformable and/or compressible, in particular deformable and/or compressible by usual assembly forces. Due to the elastic deformation and/or compression, the contact means can be applied to the ground contact over as full an area as possible and/or over a large area. For example, the contact means is at least partially made of an elastic and/or compressible, in particular structurally compressible, material.

According to a further embodiment, electrically conductive coated, conductive or non-conductive, materials or electrically conductive plastics, in particular elastomers, silicones or rubber, have turned out to be preferred materials for the contact means. Consequently, the electrically conductive coated material is itself conductive, for example a metal, or itself non-conductive, for example a plastic, a rubber or a silicone. Particularly preferably, the contact means is made of an electrically conductive coated elastomer. The contact means, in particular a contact means formed as an elastomer, preferably has a compressibility of between 10% and 40% of the original geometry. The contact means, in particular a contact means designed as an elastomer, preferably has a hardness of in the range between 40 and 75 Ufer A, in particular between 50 and 60 Ufer A, preferably exactly 50 or 65 Ufer A.

The contact means, in particular before deformation for contacting, preferably has a width which is approximately twice as large as the height and length respectively. In particular, it is provided that the contact means has at least one, preferably two, recesses.

The electrically conductive coating is produced, for example, by an electrically conductive foil, in particular of a metal, or a coating by means of chemical vapor deposition (CVD) or physical vapor deposition (PVD). Preferably, the coating includes at least one metal, in particular tin, silver, gold and/or nickel. It is further provided that the coating is formed by a copper foil coated with tin, silver, gold and/or nickel.

For example, it is provided that the contact means is made as a contact spring or a contact brush made of metal. It is further provided that the contact means comprises an electrically conductive plastic and/or an electrically conductive rubber and/or an electrically conductive silicone.

Due to the elastic deformability and/or compressibility of the contact means, it applies itself to the ground contact with a contact force, thus ensuring advantageous contacting of the ground contact for the filter circuit.

In order to ensure advantageous contacting of the circuit carrier with the at least one ground contact, according to a further embodiment it is provided that the contact means is arranged in an edge region of the circuit carrier. If several contact means are provided, the contact means are preferably arranged uniformly distributed in the edge region of the circuit carrier. In particular, the contact means are arranged directly adjacent to the edge of the circuit carrier.

A further embodiment of the electric motor provides that the contact means or the contact means are glued and/or soldered to the circuit carrier. For further simplification of assembly, it has also proved advantageous if it is provided that the circuit carrier is arranged in a cover which can be attached to the housing. When the cover is fastened to the housing, the circuit carrier is simultaneously arranged or fixed to the electric motor in such a way that the contact means is connected to the ground contact by abutting the ground contact. The suppression device with the circuit carrier is held in particular by the cover in the mounting position in which the contact means rests against the ground contact.

The above-mentioned task is further solved by a method for arranging a suppression device against electromagnetic emissions on an electric motor, comprising at least the following method steps:

Providing an electric motor with at least two terminal contacts,

Providing a suppression device having at least one circuit carrier with a filter circuit and at least one contact means,

Moving the suppression device to its mounting position on the electric motor with deformation of the contact means and simultaneous contacting of a ground contact,

Fasten the suppression in the mounting position.

The contacting of the contact means with the ground contact on the electric motor takes place by approaching the circuit carrier into the mounting position and fixing the circuit carrier in the mounting position. When approaching, the contact means deforms at least partially, in particular elastically, and thereby advantageously contacts the ground contact. Preferably, the contact means deforms in such a way that it is at least partially compressed during approach. After the suppression device is in the mounting position, the suppression device is attached to the electric motor and the contact means is held in its deformed state.

Preferably, the electric motor for the method is designed according to one of the embodiments described above. In particular, the circuit carrier has a plurality of contact means. Preferably, the contact means is or the contact means are formed as an elastomer provided with a conductive coating.

Fixing the suppression device in the mounting position can also be done indirectly by fixing a cover, in which the suppression device is held, to the electric motor.

The above-mentioned task is further solved by using a deformable, in particular compressible, electrically conductive contact means attached to a circuit carrier for contacting a filter circuit on a circuit carrier with at least one ground contact of an electric motor. Preferably, the contact means is designed as an elastomer provided with a conductive coating. In particular, the contact means is deformable by the forces prevailing during assembly. The coating comprises, for example, a tin-, gold- and/or nickel-plated copper layer or copper foil. The contact means is in particular compressible.

### BRIEF DESCRIPTION OF THE DRAWINGS

Further advantageous embodiments of the invention are apparent from the following description of the figures and the dependent claims.

It show:

FIG. 1 an example of an electric motor with suppression device in perspective view,

FIG. 2 a section through a device according to FIG. 1 in the edge area,

FIG. 3 an embodiment of an electric motor in perspective view,

FIG. 4a a perspective view of an embodiment of an interference suppression device from below,

FIG. 4b the example of FIG. 4a from above,

FIG. 4c the embodiment of FIGS. 4a and 4b in side view,

FIG. 5 an example of a filter circuit as a circuit diagram,

FIG. 6 an embodiment of an electric motor during assembly, and

FIG. 7 a schematic embodiment of a method for arranging a suppression device.

In the various figures in the drawing, the same parts are always given the same reference signs.

### DETAILED DESCRIPTION

Regarding the following description, it is claimed that the invention is not limited to the embodiments and thereby not limited to all or several features of described feature combinations, rather each individual partial feature of the/each embodiment is also of importance for the subject matter of the invention detached from all other partial features described in connection therewith for itself and also in combination with any features of another embodiment.

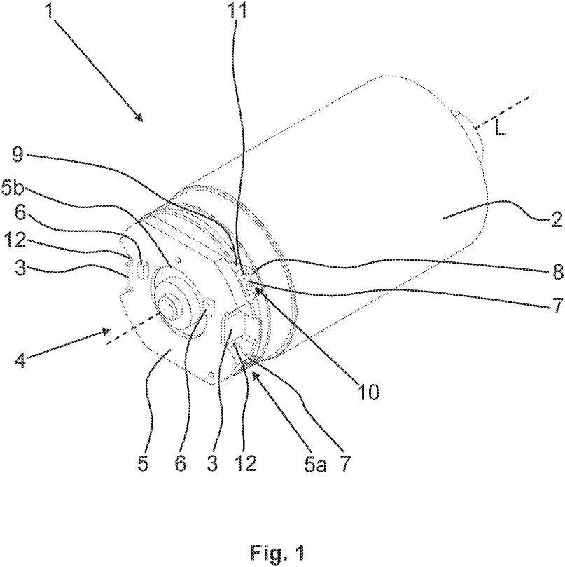

FIG. 1 shows an example of an electric motor 1 in perspective view. The electric motor 1 has a housing 2 and two terminal contacts 3, with which the brushes are contacted in this embodiment. The housing 2 is made of an electrically conductive metal. The electric motor 1 has the usual components of an electric motor 1 within the housing 2, namely at least one rotor, at least one stator and, in this embodiment, at least one commutator.

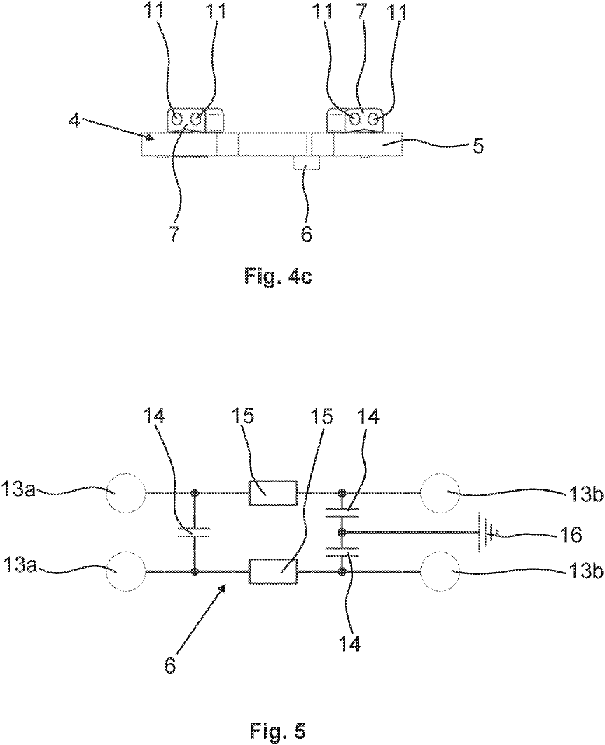

A suppression device 4 is arranged on the housing 2 of the electric motor 1, which has a circuit carrier 5 with a filter circuit 6 arranged thereon. The filter circuit 6 is electrically connected to the terminal contacts 3. Four contact means 7 are also attached to the circuit carrier 5 and electrically connected to the filter circuit 6. The filter circuit 6 has conductive connections between the components of the filter circuit 6, which are not shown separately in FIG. 1. An exemplary filter circuit 6 is shown in FIG. 5.

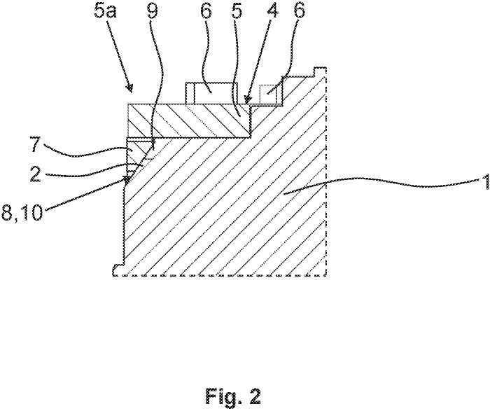

According to FIG. 1, the contact means 7 are at least partially deformed and are in contact with aground contact 8, which in this embodiment is at least partially formed by the housing 2. The housing 2 is electrically connected to the back iron. FIG. 2 shows a section through one of the contact means 7 according to FIG. 1. The contact means 7 is deformed in the area of the deformation 10 of the housing 2 and lies against the housing 2 and the brush cover 9 over the entire surface in the deformation 10. The contact means 7 is at least partially compressed according to FIG. 2 and does not extend beyond the contour of the housing 2, in particular not in the radial direction.

According to FIG. 1, the contact means 7 are arranged in the edge region 5a of the circuit carrier 5 and are distributed evenly spaced apart to each other on the circuit carrier 5. The housing 2 has four concave deformations 10, which in this embodiment are formed by caulking the housing 2 with the brush cover 9. Each of the contact means 7 is arranged in one of the deformations 10. The contact means 7 are formed and arranged in such a way that they are arranged within the deformations 10 in such a way that they do not project beyond the outer contour of the housing 2, in particular not in the radial direction, before the deformation.

In this embodiment, the contact means 7 are designed as an elastomer which is provided with a coating of at least one metal. The elastically deformable and compressible elastomer advantageously fits into the deformation 10, so that a large contact area is achieved at the ground contact 8.

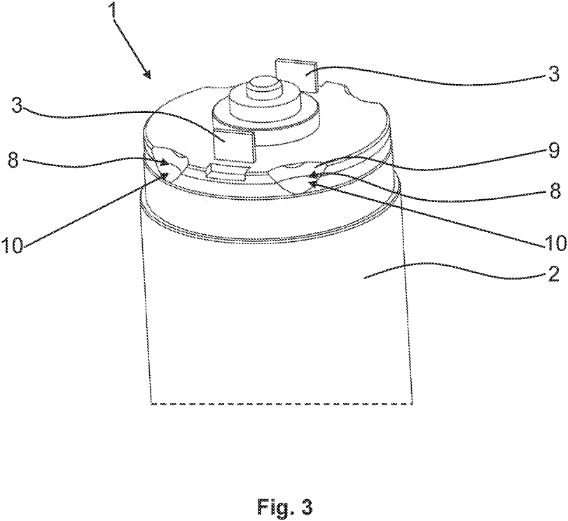

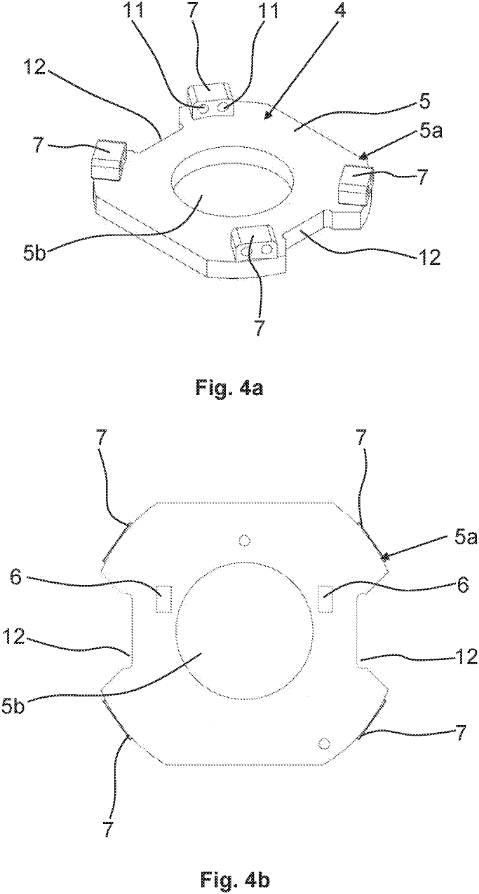

FIG. 3 shows an embodiment of an electric motor 1 in perspective view. No suppression device 4, for example according to FIGS. 4a to 4c, is yet mounted on the motor 1. The housing 2 of the motor 1 is caulked to the brush cover 9 of the electric motor 1 in the region of four concave deformations 10 arranged over the circumference. The housing 2 is deformed in the direction of the brush cover 9 in order to cooperate in a form-fitting manner with the latter. A contact means 7 can engage in each of these deformations 10 and contact the housing 2 as a ground contact 8 after the suppression device 4 has been mounted. The terminal contacts 3 of the electric motor 1 protrude essentially vertically from the electric motor 1.

A suppression device 4, which can be mounted on an electric motor 1 according to FIG. 3, is shown by way of example in FIGS. 4a to 4c. FIG. 4a shows the suppression device 4 in a perspective view from below. Four contact means 7 are arranged on the circuit carrier 5 of the suppression device 4 at uniformly spaced intervals and are conductively soldered to the circuit carrier 5 in such a way that the contact means 7 are electrically connected to the filter circuit 6. The conductive paths connecting the components of the filter circuit 6 are not shown in FIGS. 4a to 4c. According to FIGS. 4a to 4c, before deformation during assembly, the contact means 7 have a substantially rectangular shape, with a width approximately twice the length and height. Each contact means 7 has one or two central recesses 11 which pass through the contact means 7 in the length direction. The contact means 7 are made of an elastomer and have an electrically conductive coating on their surface. The contact means 7 are elastically deformable and compressible.

The terminal contacts 3 according to FIG. 1 and FIG. 3 can be soldered to the circuit carrier 5 in receiving areas 12 of the circuit carrier 5 according to FIG. 4a to FIG. 4c, so that an electrical contacting of the filter circuit 6 is realized, whereby the filter circuit 6 is electrically connected between the terminal contacts 3, for example as according to FIG. 5. The circuit carrier 5 has a central recess 5b through which the components of the electric motor can pass in the assembly position - see FIG. 1.

FIG. 5 shows an embodiment of a filter circuit 6 as a circuit diagram. The filter circuit 6 can be connected to the terminal contacts 3 of the electric motor 1 via connecting areas 13a and 13b. The filter circuit 6 comprises three capacitances 14 and two inductances 15. The ground connection 16 is provided between two capacitances 14, which is connected to a ground contact 8 - according to FIG. 1 the housing 2 and the back iron 9 - of the electric motor 1 via the contact means 7 (see, for example, FIG. 1). The inductances 15 are arranged in series between the connecting areas 13a, 13b, and the capacitances 14 are arranged in parallel between the terminal contacts 13a, 13b.

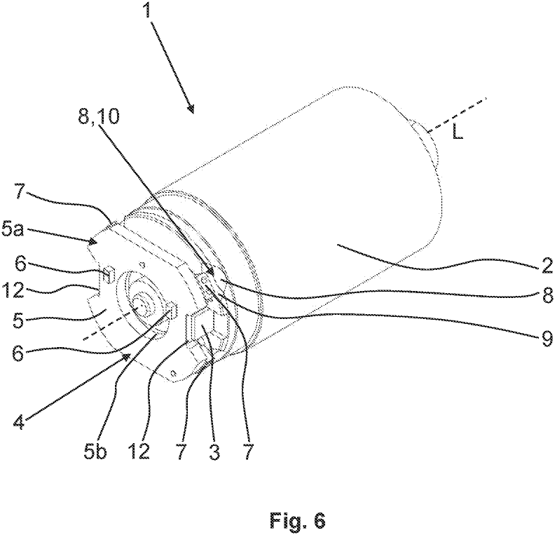

FIG. 6 shows an embodiment of an electric motor 1 during assembly. The suppression device 4 is moved in a direction along the longitudinal axis L towards one end side of the electric motor 1 so that the terminal contacts 3 engage in the receiving areas 12 and the contact means 7 come to rest in the deformations 10 with as large a contact area as possible. In FIG. 6, the contact means 7 are not yet deformed or compressed and deform, for example according to FIG. 2, when the circuit carrier 5 is in its mounting position (see FIG. 1 and FIG. 2). In this embodiment, the circuit carrier 5 is attached to the electric motor 1 by soldering the terminal contacts 3 in the receiving areas 12.

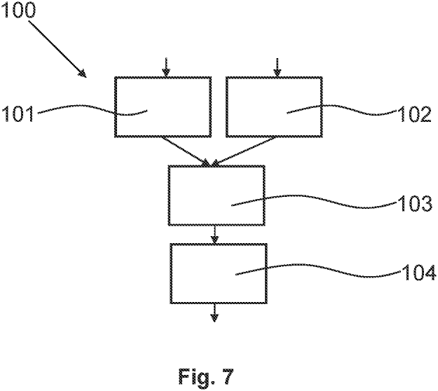

FIG. 7 shows the schematic sequence of an embodiment of a method 100 for arranging an suppression device 4 against electromagnetic emissions on an electric motor 1. First, an electric motor 1 with at least two terminal contacts 3 is provided 101, in particular according to one of the embodiments described above. Further occurs the provision 102 of a suppression device 4 with at least one circuit carrier 5 and a filter circuit 6, for example according to FIG. 5, as well as at least one contact means 7. Subsequently, the moving 103 of the suppression device 4 into its mounting position (for example according to FIG. 1) on the electric motor 1 takes place with elastic deformation of the contact means 7 respectively the contact means 7 with simultaneous contacting of the contact means 7 respectively the contact means 7 with a ground contact 8, in this case for example the housing 2. Finally, the suppression device 4 is fixed 104 to the electric motor 1, for example by soldering the terminal contacts 3 in the receiving areas 12.

The invention is not limited to the embodiments shown and described, but also includes all embodiments having the same effect in the sense of the invention. It is expressly emphasized that the embodiments are not limited to all features in combination, rather each individual sub-feature may also have inventive significance in isolation from all other sub-features. Furthermore, the invention has not yet been limited to the combination of features defined in claim 1 either, but can also be defined by any other combination of certain features of all the individual features disclosed as a whole. This means that in principle virtually any individual feature of claim 1 can be omitted or replaced by at least one individual feature disclosed elsewhere in the application.

1. An electric motor comprising a housing,
at least two terminal contacts and at least one suppression device against electromagnetic emissions, the suppression device having at least one circuit carrier with at least one filter circuit, the circuit carrier being arranged on an end side of the electric motor, and the filter circuit being electrically connected to the two terminal contacts,
at least one contact means electrically connected to the filter circuit is attached to the circuit carrier, and in that the contact means bears against a ground contact with at least partial deformation, so that the filter circuit is electrically connected to the ground contact via the contact means.

2. The electric motor according to claim 1, further comprising at least two, or at least three or at least four contact means are attached to the circuit carrier.

3. The electric motor according to claim 1, further comprising the ground contact is formed by at least one of the housing and at least indirectly or directly by an back iron of the electric motor, and wherein the contact means bears at least partially against at least one of the housing and at least indirectly or directly against the back iron.

4. The electric motor according to claim 1, further comprising the housing has at least one deformation and wherein the contact means rests in the deformation.

5. The electric motor according to claim 1, further comprising the contact means is designed and arranged such that it does not project beyond the outer contour of the housing.

6. The electric motor according to claim 1, further comprising the contact means is at least one of at least partially elastically deformed and at least partially compressed.

7. The electric motor according to claim 1, further comprising the contact means is made of an electrically conductive coated, conductive or non-conductive, material or an electrically conductive plastic, silicone or rubber.

8. The electric motor according to claim 1, further comprising the contact means is arranged in an edge region of the circuit carrier.

9. The electric motor according to claim 1, further comprising the contact means is at least one of glued and soldered to the circuit carrier.

10. The electric motor according to claim 1, further comprising the circuit carrier is arranged in a cover limiting the housing.

11. A method for arranging a suppression device against electromagnetic emissions on an electric motor, comprising at least the following method steps:
providing an electric motor with at least two terminal contacts,
providing a suppression device with at least one circuit carrier with a filter circuit and at least one contact means,
moving the suppression device into its mounting position on the electric motor while deforming the contact means and simultaneously contacting a ground contact, and
fixing the suppression device in the mounting position.

12. Use of a deformable electrically conductive coated contact means attached to a circuit carrier for contacting a filter circuit on the circuit carrier with at least one ground contact of an electric motor.

13. The electric motor according to claim 4, further comprising the deformation is in an edge region oriented in the direction of the suppression device.

14. The electric motor according to claim 4, further comprising the deformation is formed by caulking.
